(19) United States
(12) Patent Application Publication
(10) Pub. No.: US 2018/0016677 A1
(43) Pub. Date: Jan. 18, 2018

(54) AN IMPROVED SUBSTRATE SUPPORT

(71) Applicant: Applied Materials, Inc., Santa Clara, CA (US)

(72) Inventors: Subhasish ROY, Bangalore (IN); Raghav Mirle SEETHARAMU, Vivekanandanagar (IN); Umesha ACHARY, Udupi District (IN); Sanjay D. YADAV, San Jose, CA (US); Tae Kyung WON, San Jose, CA (US)

(21) Appl. No.: 15/622,700

(22) Filed: Jun. 14, 2017

Related U.S. Application Data
(60) Provisional application No. 62/361,963, filed on Jul. 13, 2016.

(51) Int. Cl. C23C 16/458; H01J 37/32; C23C 16/505; H01L 21/683; H01L 21/67

(52) U.S. Cl. CPC C23C 16/4586; H01J 37/32715; H01J 37/32082; H01J 37/32697; C23C 16/505; H01J 2237/3321; H01L 21/67103; H01L 21/6833

(57) ABSTRACT

An apparatus for processing substrates is described. More particularly, embodiments of the present disclosure relate to an improved substrate support for heating and cooling substrates using turbulent flow during processing. By creating a turbulent flow within the channels, a greater amount of heat is transferred in a shorter period of time. The present design is cost effective and advantageously provides for a more uniform distribution of temperature transfer. In one embodiment, a substrate support assembly is disclosed. The substrate support assembly includes a electrostatic chuck with a surface that is in contact with a substrate and a support plate adjacent the electrostatic chuck. The support plate includes one or more channels, one or more end spaces, and one or more plugs. The substrate support assembly also includes a shaft coupled to the support plate.

### CROSS-REFERENCE TO RELATED APPLICATIONS

This application claims benefit of U.S. provisional patent application Ser. No. 62/361,963, filed Jul. 13, 2016, which is herein incorporated by reference.

### BACKGROUND OF THE DISCLOSURE

### Field of the Disclosure

Embodiments of the present disclosure generally relate to an apparatus for processing substrates. More particularly, embodiments of the present disclosure relate to an improved substrate support for heating and cooling substrates during processing.

### Description of the Related Art

Plasma enhanced chemical vapor deposition (PECVD) is generally employed to deposit thin films on substrates, such as semiconductor substrates, solar panel substrates, and liquid crystal display (LCD) substrates. PECVD is generally accomplished by introducing a precursor gas into a vacuum chamber having a substrate disposed on a substrate support. The precursor gas is typically directed through a gas distribution plate situated near the top of the vacuum chamber. The precursor gas in the vacuum chamber is energized (e.g., excited) into a plasma by applying a radio frequency (RF) power to the chamber from one or more RF sources coupled to the chamber. The excited gas reacts to form a layer of material on a surface of a substrate that is positioned on a temperature controlled substrate support. The distribution plate is generally connected to a RF power source and the substrate support is typically connected to the chamber body providing a RF current return path.

Uniformity is generally desired in the thin films deposited using PECVD processes. For example, an amorphous silicon film, such as microcrystalline silicon film, or a polycrystalline silicon film is usually deposited using PECVD on a flat panel for forming p-n junctions required in transistors or solar cells. The quality and uniformity of the amorphous silicon film or polycrystalline silicon film are important for commercial operation.

During processing, deposition uniformity and gap fill are sensitive to source configuration, gas flow changes, or temperatures. During some of the processes, the substrate is placed onto a substrate support such as an electrostatic chuck (ESC), for processing. Chucks are used to hold a substrate to prevent movement or misalignment of the substrate during processing. Electrostatic chucks use electrostatic attraction forces to hold a substrate in position. During display processing, different chemical reactions necessitate different temperatures for uniform deposition on a substrate. Heating and cooling mechanisms have included pipes welded on a substrate support. However problems with welded pipes include non-uniform heating and cooling, the process taking a large amount of time to heat or cool the substrate, and being quite costly.

As such, a need exists for an improved substrate support.

### SUMMARY OF THE INVENTION

Embodiments of the present disclosure generally relate to an apparatus for processing substrates. More particularly, embodiments of the present disclosure relate to an improved substrate support for heating and cooling substrates during processing.

In one embodiment, a substrate support assembly is disclosed. The substrate support assembly includes an electrostatic chuck and a support plate coupled to the electrostatic chuck. The support plate includes one or more channels, one or more end spaces, and one or more plugs. The substrate support assembly also includes a shaft coupled to the support plate.

In another embodiment, a support plate is described. The support plate is adjacent an electrostatic chuck. The support plate includes one or more channels disposed within the support plate, one or more end spaces disposed within the one or more channels, and one or more plugs disposed within the one or more channels.

In another embodiment, a chamber is described. The chamber includes a chamber body defining a process volume, an electrostatic disposed within the chamber body, and a support plate coupled to the electrostatic chuck. The support plate includes one or more channels disposed within the support plate, one or more end spaces disposed within the one or more channels, and one or more plugs. The chamber may also include a shaft disposed between the support plate and the chamber body.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 shows a schematic cross-sectional view of one embodiment of a plasma processing system.

FIG. 2A shows a schematic top perspective view of a support assembly, according to one embodiment.

FIG. 2B shows a schematic bottom perspective view of a support assembly, according to one embodiment.

FIG. 3 shows a schematic bottom perspective view of a support plate, according to one embodiment.

To facilitate understanding, identical reference numerals have been used, wherever possible, to designate identical elements that are common to the figures. It is contemplated that elements and/or process steps of one embodiment may be beneficially incorporated in other embodiments without additional recitation.

### DETAILED DESCRIPTION

Embodiments described herein relate to an apparatus for processing substrates. More particularly, embodiments of the present disclosure relate to an improved substrate support for heating and cooling substrates during processing. In the description that follows, reference will be made to a PECVD chamber, but it is to be understood that the embodiments herein may be practiced in other chambers as well, including physical vapor deposition (PVD) chambers, etching chambers, semiconductor processing chambers, solar cell processing chambers, and organic light emitting display (OLED) processing chambers to name only a few. Suitable chambers that may be used are available from AKT America, Inc., a subsidiary of Applied Materials, Inc., Santa Clara, Calif. It is to be understood that the embodiments discussed herein may be practiced in chambers available from other manufacturers as well.

Embodiments of the present disclosure are generally utilized in processing rectangular substrates, such as substrates for liquid crystal displays or flat panels, and substrates for solar panels. Other suitable substrates may be circular, such as semiconductor substrates. The chambers used for processing substrates typically include a substrate transfer port formed in a sidewall of the chamber for transfer of the substrate. The transfer port generally includes a length that is slightly greater than one or more major dimensions of the substrate. The transfer port may produce challenges in RF return schemes. The present disclosure may be utilized for processing substrates of any size or shape. However, the present disclosure provides particular advantage in substrates having a plan surface area of about 15,600 cm² and including substrates having a plan surface area of about a 90,000 cm² surface area (or greater). Embodiments described herein provide a solution to challenges present during processing of larger substrate sizes.

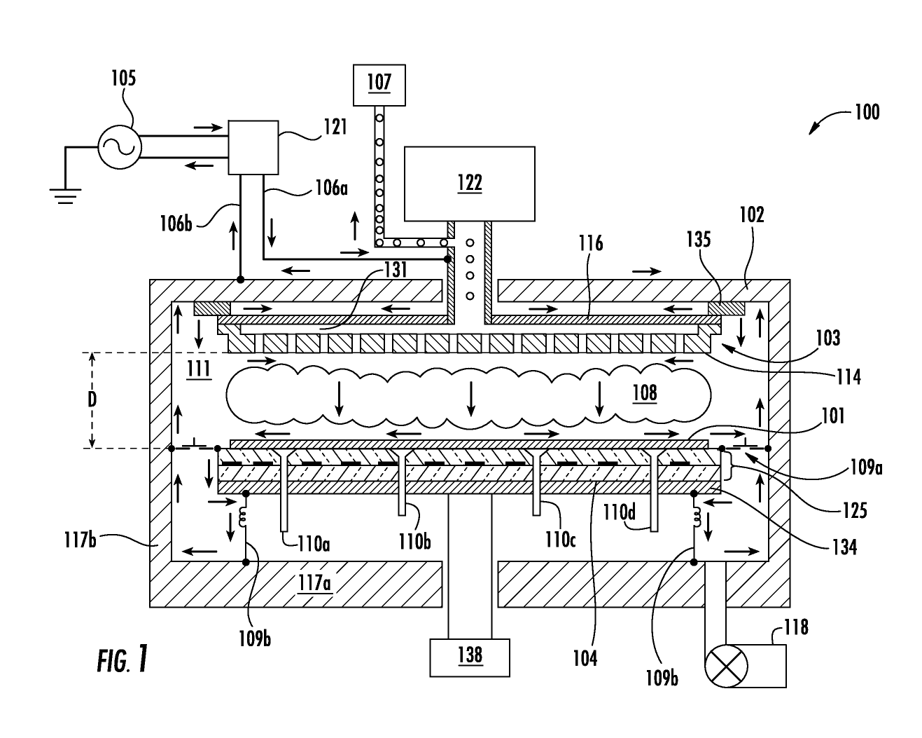

FIG. 1 is a schematic cross-sectional view of one embodiment of a plasma processing system 100. The plasma processing system 100 is configured to process a large area substrate 101 using plasma in forming structures and devices on the large area substrate 101 for use in the fabrication of liquid crystal displays (LCD's), flat panel displays, organic light emitting diodes (OLED's), or photovoltaic cells for solar cell arrays. The substrate 101 may be thin sheet of metal, plastic, organic material, silicon, glass, quartz, or polymer, among others suitable materials. The substrate 101 may have a surface area greater than about 1 square meter, such as greater than about 2 square meters.

The plasma processing system 100 includes a chamber body 102 including a bottom 117a and sidewalls 117b that at least partially defines a processing volume 111. A substrate support assembly 104 is disposed in the processing volume 111. The substrate support assembly 104 provides support the substrate 101 on a top surface during processing. The substrate support assembly 104 includes an electrostatic chuck 125 and a support plate 134. The substrate support assembly 104 may also include a shaft coupled to the support plate 134. The electrostatic chuck 125 may include a first dielectric layer, a second dielectric layer, and chucking electrodes disposed between the first dielectric layer and the second dielectric layer. The substrate support assembly 104 is coupled to an actuator 138 adapted to move the substrate support 104 at least vertically to facilitate transfer of the substrate 101 and/or adjust a distance D between the substrate 101 and a showerhead assembly 103. One or more lift pins 110a-110d may extend through the substrate support assembly 104. The showerhead assembly 103 supplies a processing gas to the processing volume 111 from a processing gas source 122. The plasma processing system 100 also includes an exhaust system 118 configured to apply negative pressure to the processing volume 111.

In one embodiment, the showerhead assembly 103 comprises a gas distribution plate 114 and a backing plate 116 arranged such that a plenum 131 is formed therebetween. In one embodiment, a remote plasma source 107 supplies a plasma of activated gas through the gas distribution plate 114 to the processing volume 111. In one embodiment, the showerhead assembly 103 is mounted on the chamber body 102 by an insulator 135.

A radio frequency (RF) power source 105 is generally used to generate a plasma 108 between the showerhead assembly 103 and the substrate support assembly 104 before, during and after processing, and may also be used to maintain energized species or further excite cleaning gases supplied from the remote plasma source 107. In one embodiment, the RF power source 105 is coupled to the showerhead assembly 103 by a first output 106a of an impedance matching circuit 121. A return input 106b to the impedance matching circuit 121 is electrically connected to the chamber body 102. In one embodiment, the plasma processing system 100 includes a plurality of first RF devices 109a and a plurality of second RF devices 109b to control the return path for returning RF current during processing and/or a chamber cleaning procedure.

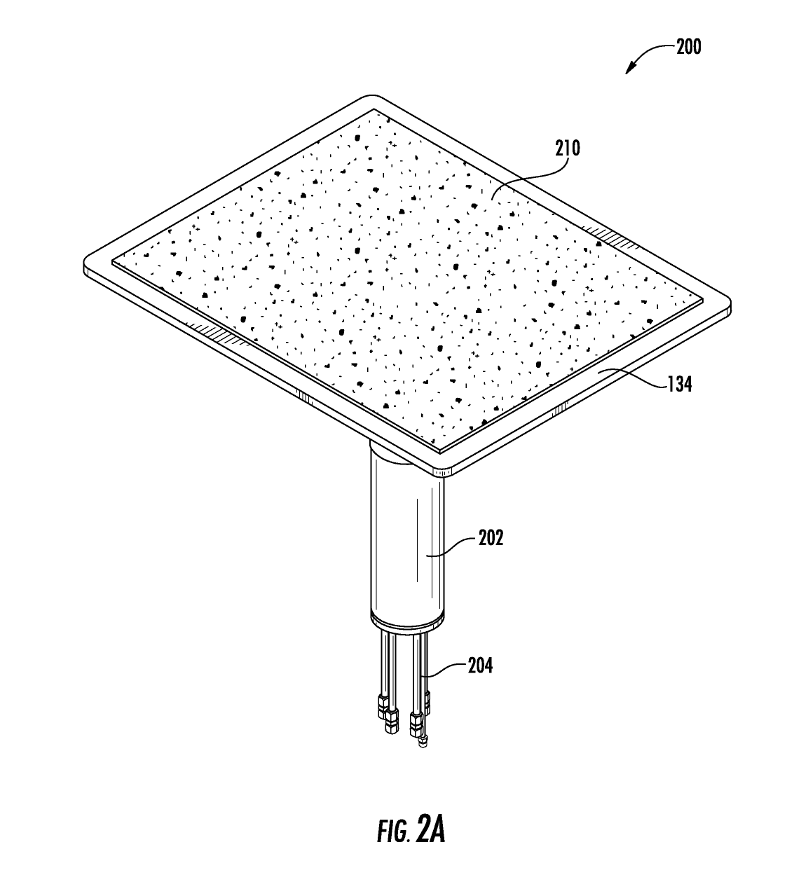

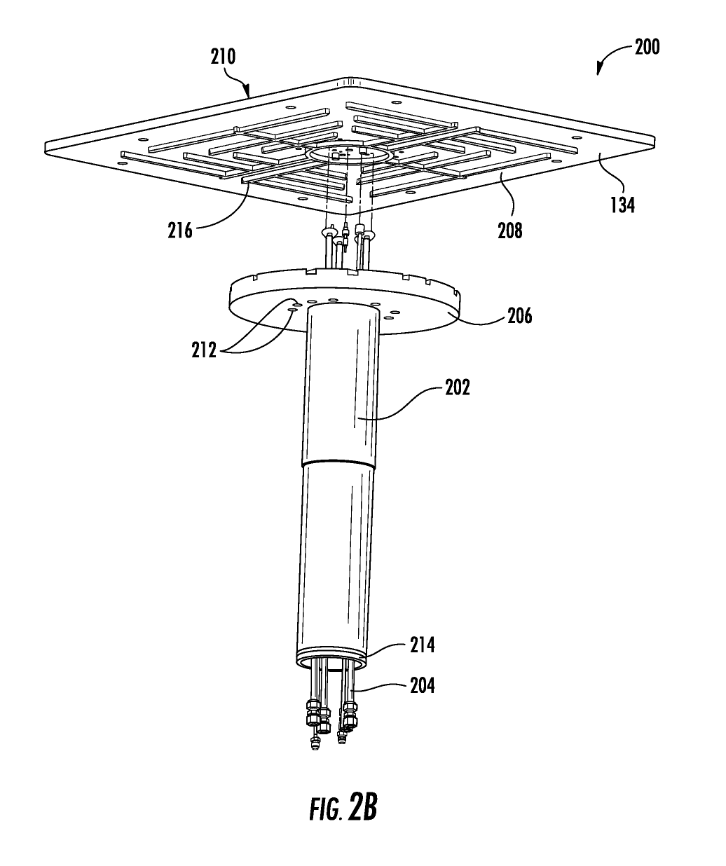

FIG. 2A shows a schematic top perspective view of a support assembly 200, according to one embodiment. FIG. 2A is a partial view of the support assembly 200. The electrostatic chuck 125 is not shown in FIG. 2A for clarity. The support assembly 200 may be the same substrate support assembly 104, seen in FIG. 1. The support assembly 200 includes the support plate 134, the electrostatic chuck 125, and a shaft 202. In one embodiment, the electrostatic chuck 125 is bonded to a first side 210 of the support plate 134 using pressure sensitive adhesive. The electrostatic chuck 125 may be ceramic.

The shaft 202 may be a hollow tubing that provides for connections 204 to go through. In one embodiment, the connections 204 include an electrostatic chuck power connection, a temperature probe connection, a first fluid connection providing for fluid directed towards the support plate 134, a second fluid connection providing for fluid directed away from the support plate 134, a gas connection, among others. In one embodiment, the connections 204 may include an RF connection. The shaft 202 may be an aluminum tubing. In one embodiment, the shaft 202 has threads 214 at opposite ends of the hollow tubing, as seen in FIG. 2B. The threads 214 may be used to connect the shaft to a connecting plate 206.

FIG. 2B shows a schematic bottom perspective view of a support assembly, according to one embodiment. The connecting plate 206 connects the shaft 202 to the support plate 134. In one embodiment, the connecting plate 206 threads onto the shaft 202. The connecting plate 206 and the shaft 202 may be connected to the support plate 134 on a first side 208, as seen in FIG. 2B. The first side 208 is opposite the second side 210. The second side 210 is adjacent to the electrostatic chuck 125. In one embodiment, the connecting plate 206 includes a plurality of recesses 212 adjacent to and circumferentially around the shaft 202. In one embodiment, the connecting plate 206 and the shaft 202 are connected to the support plate 134 using fasteners such as screws or bolts that are disposed within the plurality of recesses 212. The plurality of recesses may provide for attachment of the connecting plate 206 to the support plate 134. The connecting plate 206 may be any shape including circular, square, rectangular, or hexagonal. The connecting plate may be made of aluminum.

The support plate 134 includes a plurality of channels 216 on the first side 208. In one embodiment, the plurality of channels 216 extend orthogonal and parallel to one another. The plurality of channels 216 may be formed in any pattern, for example a zig-zag pattern. The plurality of channels 216 may be formed in various ways including gun drilled into the body 308, 3D printed, and using foam-casting techniques. The plurality of channels 216 may also be formed by splitting the aluminum body 308 in half, milling the plurality of channels 216 into the aluminum body 308 and then attaching the two halves with the plurality of channels 216 formed therein back together.

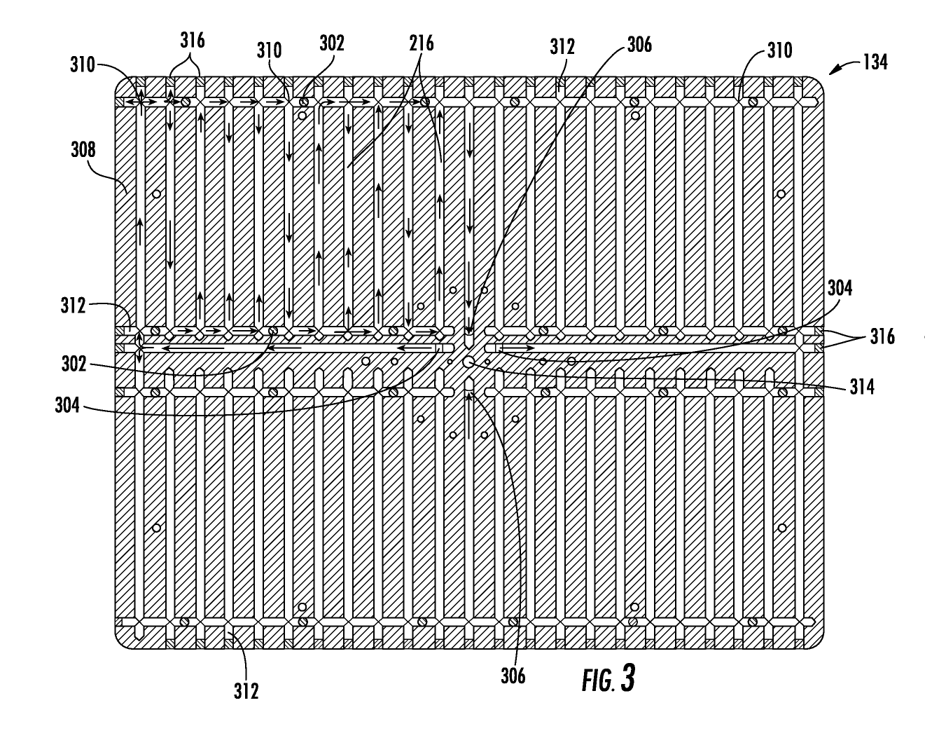

FIG. 3 shows a bottom perspective view of a support plate 134, according to one embodiment. The support plate 134 includes the plurality of channels 216, a plurality of plugs 302, a plurality of channel openings 304, a plurality of channel exits 306, a plurality of channel intersections 310, a plurality of end spaces 312, a plurality of end plugs 316, center 314, and a body 308.

The plurality of channels 216 include a plurality of openings 304. Fluid enters the channels through the plurality of openings 304 located adjacent the center 314 and proceeds towards the outer edge of the support plate 134, as indicated by the arrows. The fluid flows within the plurality of channels 216 that are dispersed throughout the body 308 of the support plate 134. The plurality of plugs 302 located within the plurality of channels 216 directs the flow of fluid. The plurality of plugs 302 may be located in various patterns within the plurality of channels 216. In one embodiment, the plurality of plugs 302 are within the same channel. In another embodiment, the plurality of plugs 302 are within different channels. In yet another embodiment, the plurality of plugs 302 are within the channels parallel to the channel containing the plurality of channel openings 304. The plurality of plugs 302 may have tapered, rounded, or chamfered ends. The plurality of plugs 302 may be press-fitted into the plurality of channels 216. The plurality of plugs 302 may be larger than the diameter of the plurality of channels 216 so that a tight seal is formed between the plurality of plugs 302 and the walls of the plurality of channels 216. In one embodiment, the fluid flows in a zig-zag pattern through the plurality of channels 216 starting from the outer edge and continuing towards the center 314.

The fluid exits the plurality of channels through the plurality of channel exits 306. The plurality of channel exits 306 connects with the connections 204 located within the shaft 202 to direct fluid away from the support plate 134. The fluid travels through the plurality of channels 216 and in various directions after reaching the plurality of intersections 310. In one embodiment, a plurality of end spaces 312 are located adjacent a plurality of end plugs 316. The plurality of end spaces 312 may be located adjacent the plurality of intersection 310 of the plurality of channels 216. As such, the plurality of end spaces 312 may be dispersed throughout the support plate 134 including adjacent the outer edge and the center 314. The plurality of end plugs 316 may be substantially similar to the plurality of plugs 302. In one embodiment, the plurality of end plugs 316 are located towards the edges of the support plate 134. The plurality of end spaces 312 advantageously causes turbulent flow of the fluid flowing within the plurality of channels 216. Additionally, the non-swept spaces located adjacent the plugs 302 and non-swept spaces disposed adjacent to the plurality of intersections 310 and adjacent the center 304 contribute to the turbulent flow. The turbulence in flow advantageously provides for a greater heat transfer and decreased amount of fluid necessary to cool the adjacent electrostatic chuck 125 and substrate 101. In one embodiment, the fluid utilized to control the temperature of the electrostatic chuck 125 is between 5° C. and 100° C. In another embodiment, the turbulence in flow may provide for a greater heat transfer and decreased amount of fluid necessary to heat the adjacent electrostatic chuck 125 and substrate 101. In one embodiment, the temperature changes between 10° C./10 min to 40° C./10 min plasma process. In one embodiment, by alternating hot and cool fluid within the plurality of channels 216 provides for finite temperature transfer and control of the temperature of the electrostatic chuck 125.

The plurality of channels adjacent the support plate advantageously provide for heat transfer from the electrostatic chuck and substrate to the fluid within the plurality of channels. By creating a turbulent flow within the channels, a greater amount of heat is transferred in a shorter period of time. The present design is cost effective and advantageously provides for a more uniform distribution of temperature transfer. Additionally, the more uniform control of heat transfer leads to a more uniform deposition of the substrate.

While the foregoing is directed to embodiments of the present disclosure, other and further embodiments of the disclosure may be devised without departing from the basic scope thereof, and the scope thereof is determined by the claims that follow.

What is claimed is:

1. A substrate support assembly comprising:
an electrostatic chuck;
a support plate coupled to the electrostatic chuck comprising:
one or more channels disposed within the support plate;
one or more end spaces disposed within the one or more channels; and
one or more plugs; and
a shaft coupled to the support plate.

2. The substrate support assembly of claim 1, wherein the shaft comprises a plurality of connections disposed within the shaft.

3. The substrate support assembly of claim 1, further comprising one or more end plugs adjacent to the end spaces.

4. The substrate support assembly of claim 1, wherein the one or more plugs are disposed within the one or more channels.

5. The substrate support assembly of claim 1, wherein the one or more channels are disposed in a zig-zag pattern.

6. The substrate support assembly of claim 1, wherein the support plate further comprises one or more channel openings disposed near a center of the support plate.

7. The substrate support assembly of claim 1, further comprising a connecting plate disposed between the support plate and the shaft.

8. A support plate adjacent an electrostatic chuck comprising:
one or more channels disposed within the support plate;
one or more end spaces disposed within the one or more channels; and
one or more plugs disposed within the one or more channels.

9. The support plate of claim 8, wherein the one or more channels are disposed in a zig-zag pattern.

10. The support plate of claim 8, wherein the support plate further comprises one or more channel openings disposed near a center of the support plate.

11. The support plate of claim 8, wherein the one or more plugs have a rounded edge.

12. The support plate of claim 8, further comprising one or more channel intersections disposed where the one or more channels intersect each other.

13. The support plate of claim 8, further comprising one or more end plugs adjacent to the one or more end spaces.

14. A chamber comprising:
a chamber body defining a process volume;
an electrostatic chuck disposed within the chamber body;
a support plate coupled to the electrostatic chuck comprising:
one or more channels disposed within the support plate;
one or more end spaces disposed within the one or more channels; and
one or more plugs; and
a shaft disposed between the support plate and the chamber body.

15. The chamber of claim 14, wherein the shaft comprises a plurality of connections disposed within the shaft.

16. The chamber of claim 14, further comprising one or more end plugs adjacent to the end spaces.

17. The chamber of claim 14, wherein the one or more plugs are disposed within the one or more channels.

18. The chamber of claim 14, wherein the one or more channels are disposed in a zig-zag pattern.

19. The chamber of claim 14, wherein the support plate further comprises one or more channel openings disposed near a center of the support plate.

20. The chamber of claim 14, further comprising a connecting plate disposed between the support plate and the shaft.
